(19) United States
(12) Patent Application Publication
(10) Pub. No.: US 2011/0209743 A1
(43) Pub. Date: Sep. 1, 2011

(54) PHOTOVOLTAIC CELL APPARATUS

(76) Inventor: Barry Clive, London (GB)

(21) Appl. No.: 13/062,107

(22) PCT Filed: Sep. 1, 2009
(86) PCT No.: PCT/GB09/51099

§ 371 Date: May 10, 2011

(30) Foreign Application Priority Data
Sep. 4, 2008 (GB) 0816113.5

(51) Int. Cl. H01L 31/052; H01L 31/024

(52) U.S. Cl. 136/246; 136/259

(57) ABSTRACT

Photovoltaic apparatus comprising a photovoltaic cell comprising an optical component of transparent material of cross section having a first surface forming an entry aperture for solar radiation, a second surface forming an exit aperture for the solar radiation passing through the entry aperture, opposite surfaces which are curved in shape, photovoltaic material positioned to receive solar radiation from the exit aperture, the opposite side surfaces being shaped to provide total internal reflection of solar radiation passing from the entry to the exit apertures, a mirror surface being positioned to reflect radiation away from one of said side surfaces.

### BACKGROUND

Over the past decade or so there has been a lot of development of optical systems that concentrate sunlight in order to increase the electricity produced from photovoltaic cells.

Examples of earlier designs include the present inventor's earlier patent applications:

1. GB 0511366.7 filed on 3 Jun. 2005 entitled Solar Concentrator System;

2. PCT/GB2006/002021 filed on 2 Jun. 2006 and entitled Solar Concentrator.

Whilst such an arrangement works well, it does use moving components and in many circumstances it is desirable not to have moving components which is more cost effective due to its simplicity, lack of maintenance and enhanced collateral benefits.

Providing a fixed photovoltaic cell apparatus which can collect efficiently the suns rays as it moves across the sky can be difficult.

Reducing the amount of expensive photovoltaic cell material is desirable. Increasing the overall efficiency of photovoltaic apparatus is desirable.

In this specification we will refer to “solar radiation” by which we mean radiation received directly (or via mirrors) from the sun - what is often referred to as “sunlight” - and “ambient light”, by which we mean the light from the rest of the sky other than direct sunlight and which comprises for the most part scattered or refracted sunlight. It is desirable in some circumstances to collect solar radiation and produce electricity and also illuminate the inside of a building.

US-A-4143234 shows a solar collector which uses total internal reflection. This is a stand-alone collector which does not include a mirror for directing radiation which has missed the entry aperture to the entry aperture adjacent solar collector. Only one side of the photovoltaic material is used to collect radiation. There is no cooling of the device.

US-A-4248643 discloses an array of sonar cells which are cooled.

US-B-6384320 discloses a solar concentrator which has an array of cells.

In none of the cases referred to is there provided a mirror for collecting radiation which has missed an entry aperture to direct the radiation to an adjacent entry aperture.

### SUMMARY OF THE INVENTION

The present invention provides, according to a first aspect, photovoltaic apparatus comprising an optical component of transparent material of cross section having a first surface forming an entry aperture for solar radiation, a second surface forming an exit aperture for the solar radiation passing through the entry aperture, opposite surfaces which are curved in shape, and photovoltaic material positioned for receiving solar radiation from the exit aperture, the opposite surfaces being shaped to provide total internal reflection of solar radiation passing from the entry to the exit apertures, a mirror surface being provided adjacent at least one of the opposite surfaces to reflect radiation away from said adjacent surface.

The opposite surfaces may be parabolic or hyperbolic.

There may be provided four side surfaces curved so as to provide total internal reflection.

The photovoltaic material preferably has a first face generally facing the first curved side surface to receive radiation from said first curved surface and a second opposite face generally facing the second curved side surface to receive radiation from said second curved surface.

Preferably a plurality of such photovoltaic cells are arranged side by side to form a panel and the optical axes of the optical components are parallel to each other but at an angle to the plane of the panel. In this case, we preferably provide a mirror surface between each optical component to reflect solar radiation which would impinge on a side surface rather than the entry aperture to the entry aperture of an adjacent photovoltaic cell.

The present invention further provides, according to a second aspect, photovoltaic apparatus comprising:
one or more (preferably fixed) photovoltaic cells for receiving radiation (usually solar radiation);
cooling means for cooling the photovoltaic cells, (which may include a liquid such as water to remove the heat);
heat transfer means for transferring the heat removed by the cooling means from the photovoltaic cells to a heat store (such as a water container);
means to extract the heat from the heat store (usually at a subsequent time, for example, at night).

Optical means may be provided to concentrate the solar radiation on to the photovoltaic cells, (which optical means may include a lenticular element). Means may be provided to allow at least some of the solar radiation to pass through the apparatus.

To meet the some or all of the problems outlined above, in a preferred arrangement, we may use mono-crystalline photovoltaic cells identical in cost with those for standard photovoltaic panels (reducing cost of more sophisticated cells), using an optical system that enables the use of substantially less area of cell for the same electricity generation, and cooling the photovoltaic cell so as to increase its efficiency, reusing the waste heat which is generated.

Thus we save the cost of the expensive component, the cell, and keep down the rest of the module cost so that overall cost of electricity generated is reduced substantially.

Alternatively, because we use an optical element to concentrate the radiation we use less photovoltaic material than otherwise and in some circumstances this can allow the use of more sophisticated and expensive photovoltaic material.

Furthermore, in a preferred photovoltaic apparatus appropriate configuration can be included in the envelope of a building, whether roof or wall, so that the frame and envelope of the building can be the frame and envelope of the module with consequent cost savings and the apparatus is protected from the elements and wind loading thus reducing the cost of these components considerably. Sometimes outer transparent skin can act as a UV filter permitting lower cost polymer (such as polystyrene) optical elements.

Further benefits of integrating the photovoltaic apparatus in a building include allowing the illumination of the interior with ambient light, which has the added benefit that it has a lower heat level than any artificial illumination. Another benefit is that in order to make the cells work more efficiently they should be cooled. If this cooling is done actively, the heat can be used for water or space heating and creating ventilation. Other benefits are that the direct sunlight is shaded from the interior of the building and therefore the cooling load on the building is greatly reduced. These cost and carbon savings if fully used greatly exceed the electricity generated and therefore make a solar installation that is affordable.

Preferably the plurality of photovoltaic cells are arranged side by side to form a panel and the optical axes of the optical components are parallel to each other but at an angle to the plane of the panel. In this case, we preferably provide a mirror surface between each optical component to reflect solar radiation which would impinge on a side surface rather than the entry aperture to the entry aperture of an adjacent photovoltaic cell.

The present invention provides, according to another aspect, apparatus comprising a plurality of photovoltaic cells some or all of which comprise an optical component of transparent material (usually solid but in an alternative arrangement including a transparent outer surface and inner transparent liquid such as water) of cross section having a first (generally upper) surface forming an entry aperture for solar radiation (i.e. direct sunlight from the sun), opposite (usually side) surfaces (which may be curved in shape), photovoltaic material (which preferably comprises mono-crystalline photovoltaic material) mounted opposite (generally lower) to the first surface for receiving solar radiation from the entry aperture, the opposite side surfaces being shaped to provide total internal reflection of solar radiation passing from the entry aperture to the photovoltaic material, the apparatus being formed so that ambient light (light other than solar radiation) may pass through the apparatus, whereby solar radiation provides electricity from the photovoltaic material and ambient light passes through the apparatus.

Such an arrangement is particularly useful for use in buildings such as glass houses or conservatories or glass roofs on shopping centres. Thus, the apparatus may be formed into panels, the solar radiation, that is the rays direct from the sun are directed to photovoltaic material to produce electricity, and also to provide heat by cooling of the photovoltaic material, but ambient light which passes to the panel from angles other than directly from the sun, may pass through the panel to provide light within the building.

### BRIEF DESCRIPTION OF THE DRAWINGS

Preferred arrangements of the invention will now be described by way of example and with reference to the accompanying drawings in which:

FIG. 1 is a section of a photovoltaic cell apparatus for use in apparatus of the invention;

FIG. 2 is a transverse section of a solar panel incorporating a plurality of photovoltaic cells of the type shown in Figure land associated optical components;

FIG. 3 is a transverse section of a solar panel incorporating a plurality of photovoltaic cells of the type shown in FIG. 2 and associated optical components but orientated with the panel generally vertical;

FIG. 4 shows ray traces for light rays passing through a photovoltaic cell of the type shown in FIG. 1;

FIG. 5 shows a building (such as a house or a greenhouse or glasshouse) incorporating panels of the type shown in FIGS. 2 and 3;

FIGS. 6 and 7 show transverse sections of solar panels similar to those of FIGS. 2 and 3 for use on solid horizontal or vertical outside surfaces respectively of a building;

FIG. 8 is a section of an alternative photovoltaic cell apparatus in which the photovoltaic material is arranged generally normal to the entry aperture and both sides of the photovoltaic material receive radiation from the entry aperture;

FIG. 9 is a section of a plurality of cells of the type shown in FIG. 1 at right angles to the section of FIG. 1;

FIG. 10 is a section of a plurality of cells of the type shown in FIG. 8 at right angles to the section of FIG. 8, and

FIG. 11 is a section of a plurality of cells arranged in groups, wherein a mirror surface for one group of cells directs radiation to the entry apertures of a cell or cells in an adjacent group.

### DESCRIPTION OF PREFERRED EMBODIMENTS OF THE INVENTION

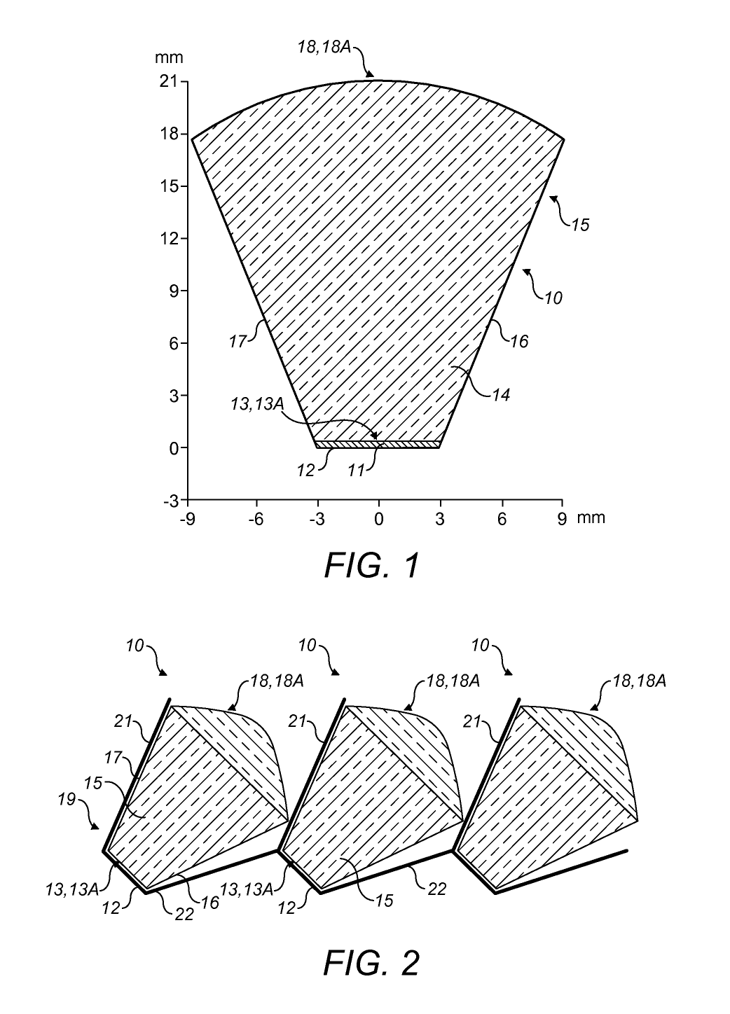

FIG. 1 is a section of a photovoltaic cell apparatus 10 for use in apparatus of the invention. The section is a transverse section, the photovoltaic cell apparatus 10 extending out of the paper as an extruded profile. (Indeed, the material of the apparatus may be of extruded plastic material.)

The apparatus of FIG. 1 comprises a single photovoltaic cell 12 in the form of a strip 11 of photovoltaic material which in this case comprises a relatively lower cost mono-crystalline photovoltaic material. Thus the photovoltaic cell 12 is attached to and in communication with a lower surface 13 of an optical component 15 comprising solid transparent material 14, the cross section shape of which is clear from FIG. 1. Thus there are provided opposite shaped curved (side) surfaces 16, 17 which are generally parabolic or hyperbolic in shape, and an upper surface 18 which may in some circumstances be flat but is usually of lenticular form. The upper surface 18 provides an entry aperture 18A and the lower surface 13 provides an exit aperture 13A for light (solar radiation) impinging on the upper surface 18. The transparent material may be any transparent material such as perspex, PMMA, polystyrene, polycarbonate, glass, or borosilicate glass suitable for the circumstance, but should be transparent to solar radiation, and of a known refractive index. The shape of the surfaces 16, 17 will depend upon, amongst other things, the refractive index. The photovoltaic cell 12 may be adhesively connected to the lower surface 13 but in that case the adhesive must be transparent to the relevant solar radiation.

Alternatively, because we use an optical element to concentrate the radiation we use less photovoltaic material than otherwise and in some circumstances this can allow the use of more sophisticated and expensive photovoltaic material In order to optimise efficiency and cost a so called Float Zone silicon may be used as the preferred photovoltaic material. This material is grown as a cylindrical crystal of up to about 150mm diameter and normally cut into semi-square wafers.

If almost the entire wafer is used as would be the case in our application with 2 dimensional concentration then we would can use an additional 35% of silicon from the wafer. With this material, used to capture almost all the direct sunlight during the year we would concentrate about 4.5 times depending on refractive index of the material for a single face cell and about 9 times for a bifacial cell (see later) in the 2dimensional configurations with the addition of another 35% benefit of full cell utilisation.

The exact shape of the surfaces 16, 17 and the lenticular upper surface 18 will depend upon the refractive index of the material, the acceptance angle and the angular disposition of the optical element 15 with respect to the incoming solar radiation. Optimisation to minimise optical and cell material use and direct sunlight ingress whilst maximising direct sunlight capture and ambient light ingress will require ray tracing It will be immediately seen that because of the use of the lenticular upper surface 18 and the relative orientation of the two opposite shaped surfaces 16, 17, the solar radiation which is passed to the photovoltaic cell 12 is increased, and the width of the strip of photovoltaic cell 12 is narrower than would otherwise be the case.

The shaped surfaces 16, 17 and the refractive index are arranged so that there is total internal reflection at the surfaces 16, 17 by the incoming solar radiation.

Referring back to FIG. 1, the cross-sectional shape of the optical component 15 is generally wedge shaped and indeed the shaped surfaces can be flat, but we prefer to use that the cross-sectional shape of the optical component 15 is a solid Compound Hyperbolic Concentrator (CHC) or Compound Parabolic Concentrator (CPC) optical element (or an approximation to them, i.e. we start with such a curve and may modify it slightly in the light of ray tracing for a particular application based on perhaps the exact positioning of the apparatus) which more effectively concentrates sunlight onto the photovoltaic cell 12 attached to its exit aperture 13A.

The transparent material 14 is usually a linear extrusion (whether in fact extruded or moulded.

The benefit of the lenticular entry aperture is that there is good concentration without the need to have a reflecting surface on the lower part of the sides and that the quantity of material for the same concentration is significantly reduced from a CPC.

The above components provide a photovoltaic component 10.

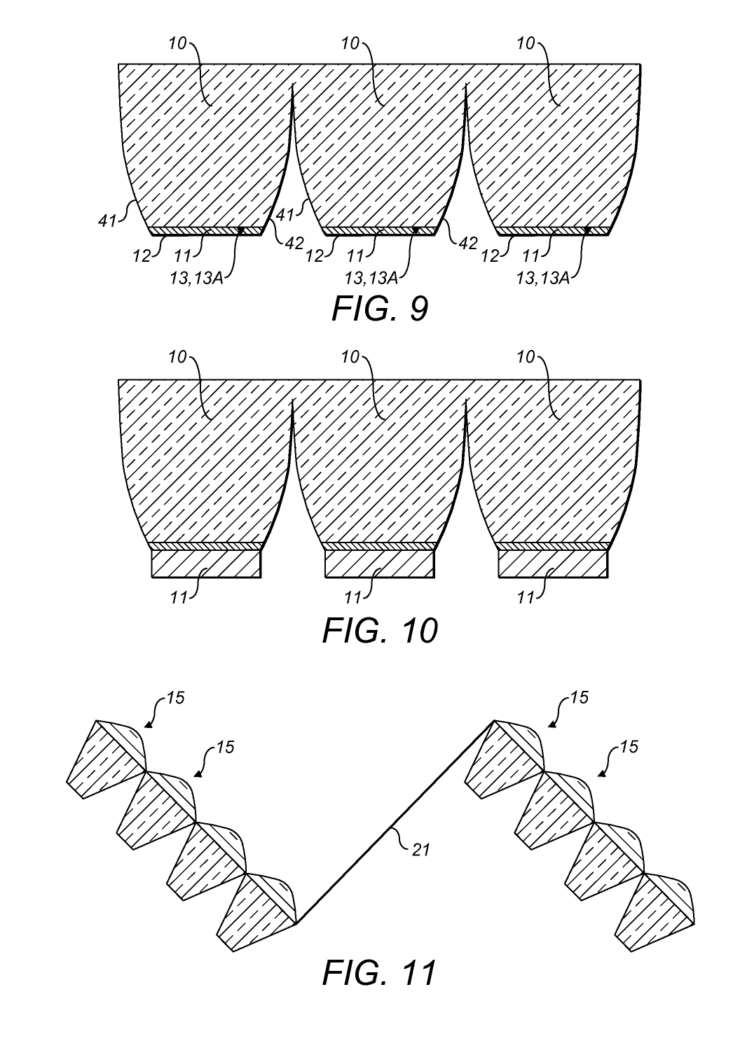

Whilst in one arrangement the photovoltaic component may be a linear length of the cross section shown in FIG. 1 (which allows extrusion of the plastic part of the apparatus) the amount of photovoltaic material used may be reduced further by arranging for a plurality of these cells to be arranged side by side as is shown in FIG. 9 which shows a section of a plurality of cells of the type shown in FIG. 1 at right angles to the section of FIG. 1. This shows that the side surfaces 41, 42 in this section may also be of compound parabolic or hyperbolic shape. Such an arrangement in which each photovoltaic component 10 includes four side surfaces 16, 17, 41, 41 will usually require moulding rather than extrusion.

FIG. 4 shows ray traces for a component 10 as shown in FIG. 1 for solar radiation arriving at different angles. Thus when the sun is high in the sky, the arrangement is as shown in FIG. 4A, and when the sun is low in the sky, is as shown in FIG. 4B.

FIG. 2 shows how a number of lengths of photovoltaic components 10 (which may comprise lengths having the cross section of FIG. 1 throughout or may be of the type shown in FIG. 9) may be arranged side-by-side in a typical application for use, for example in a greenhouse (glasshouse) or conservatory or otherwise to replace normal transparent (glass) panels in buildings. The arrangement of FIG. 2 shows three photovoltaic components 10 side-by-side although of course there may be a much larger number side-by-side to form a panel 19 of desired dimensions. In this case the panel 19 of photovoltaic components 10 is arranged so that the panel will be mounted generally south facing in the northern hemisphere and horizontally although any angle between approximately vertical and a north facing roof up to about latitude angle less about 24 degrees with the optical axis of the individual optical components 15 arranged generally close to the latitude angle to the horizontal, the exact number of degrees depending upon the latitude of the point on the earth's surface where the photovoltaic component is being mounted.

Referring again to FIG. 2, the entrance aperture 18A for the sun's rays for each photovoltaic component 10 is the top line and the exit aperture 13A is the bottom line. The sides are two (generally hyperbolic) curves (which in this case are close to straight lines) that are designed to maximise total internal reflection for all rays within the acceptance angle where this is the cross-section through an extruded profile.

FIG. 2 shows the optical system designed to maximise the direct the solar radiation (sunlight) concentrated onto the cell throughout the year for a horizontal surface at about 45 degrees latitude whilst protecting the interior space from direct sunlight for most of the year, and also permitting the ambient light to reach the interior of the space as far as possible. This is achieved by using a combination of the transparent solid optical element and a mirror surface 21. It should be noted that the mirror 21 is separated from the optical component 15 with the side of the mirror 21 towards the optical component being non-reflective where it is desired to reduces the amount of direct sunlight passing through the array of cells (for example to the interior of a building to avoid heating it, or conversely may be reflective where it is desired that more ambient light is transmitted into the building. The mirror surface 21 is positioned so as to reflect radiation away from the adjacent side surface 17 of the photovoltaic component 10 to the entrance aperture 18A of the adjacent photovoltaic component 10.

It will be understood that the optical element 15 is designed for receiving the solar radiation, that is sunlight direct from the sun and focusing that on to the photovoltaic material 13. This is done by means of the total internal reflection at the side surfaces 16,17.

One of the advantages of the present arrangement is that ambient light, that is general light from the sky arrives at the panel 19 at different angles and much of this light can pass through the optical component thereby allowing for illumination below the panel 19. Thus this arrangement of the invention is particularly useful in, for example, glass houses or conservatories. Electricity can be produced by the photovoltaic material from direct sun light, and the interior of the building receives other ambient light. In this way the interior of the building is illuminated but is not overheated since most of the sun's direct rays will be collected by the photovoltaic cells. Furthermore, electricity is produced by the photovoltaic cells, and heat is also produced by cooling of them. One of the reasons for the ability to separate the sun's rays from ambient light is that the sun's rays are directed by total internal reflection at the shaped side surfaces of the optical component, but ambient light strikes those surfaces at other angles and can pass through those surfaces without internal reflection.

A lower protective sheet 22 of transparent material which permits the ambient light to pass downwardly through the component 10 and enter an interior space below without allowing dust to reach the surfaces of the component 10 from below.

The cell 15 is mounted on a heat sink. It will be noted that because the cell 15 is open at its lower surface, it is cooled by the air from below to provide air cooling. In some circumstances the cell 15 is provided at a small inclination to the horizontal so that when a transparent sheet is mounted under the unit, the cooling air flow is increased because of laminar flow effects and stopped from entering the interior space.

The laminar flow effect is greatly enhanced when this type of configuration is in the vertical.

The whole panel 19 includes an upper transparent film or sheet 23 for protection of the component 10 from dust and the elements from above.

In a particularly preferred embodiment, the photovoltaic cell 12 may be cooled by means of cooling apparatus which may comprise tubes of water or heat pipes mounted thereon and in this case the lower protective sheet 22 is not required and a sheet or film of transparent material can be mounted under the configuration.

In FIG. 2, the latitude is presumed to be 45 degrees, but a horizontal structure suited to other latitudes by changing the tilt of the components 10 to the horizontal.

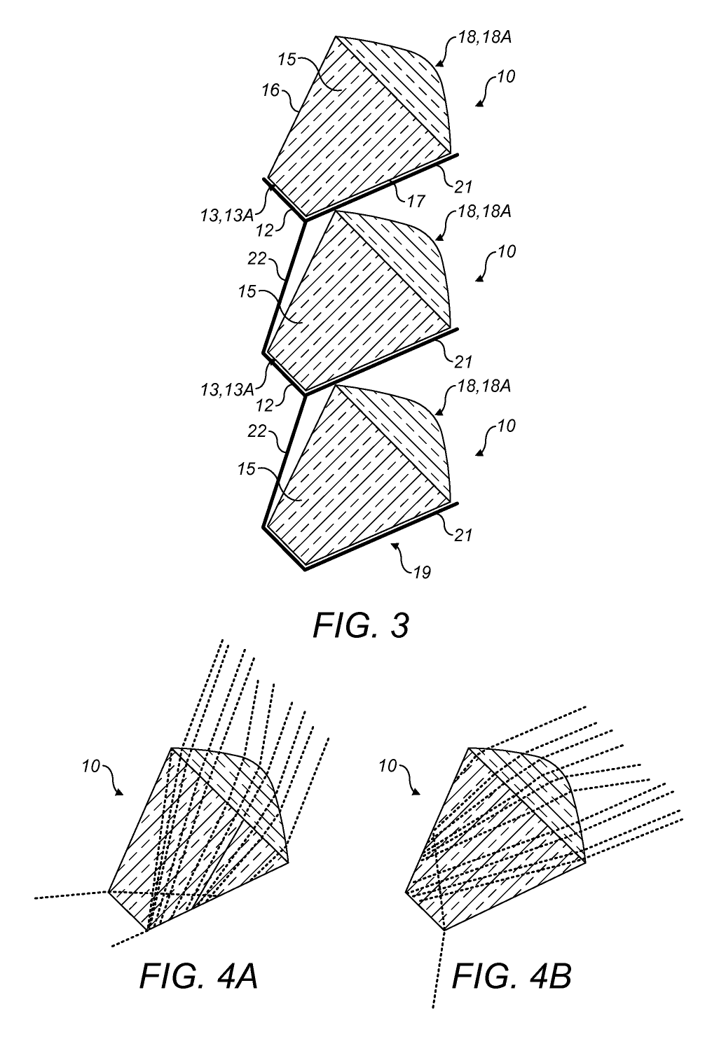

One advantage of the system is that the same combination of optical elements can be used for any surface that would have sight of the sun. For example FIG. 3 shows a similar arrangement suitable for use on a vertical wall.

Although the arrangement of FIG. 3 does show a mirror 21, there are some advantages in providing mirrors 21 as shown in other Figures to produce a greater concentration of sunlight on the cells.

Another consideration is heat. As only up to 25% of the light is converted to electricity by the silicon cell 12 (more likely about 18%) it is desirable to remove the heat for the cell to work efficiently.

This may be done by a tube, carrying heat transfer liquid such as water, behind the cell.

Alternatively a metal heat sink is attached to the photovoltaic cell 12 which heat sink is accessible to allow air flow for cooling.

A third apparatus uses a heat pipe attached to the photovoltaic cell 12 and the heat is removed to be used or dissipated elsewhere.

A fourth apparatus uses liquid flow in the body of the optical element so that the optical element is only a hollow profile and the liquid is involved with the refraction process.

We have realised that the heat generated is a valuable resource that can be used for water heating, space heating and to drive ventilation.

Configurations that are air cooled and not requiring ambient light to reach the building interior could be just mounted on a sheet of aluminium, bent or pressed to the right angles.

We now refer to FIG. 8 which is a section of an alternative photovoltaic cell apparatus in which the strip 11 of photovoltaic material instead of being provided as a strip attached to a lower surface 13 of the optical component 15 is arranged adjacent that lower surface but within a slot (which provides the exit aperture 13A) the body of the optical component and is in the form of a strip of photovoltaic material arranged generally normal to the entry aperture. As before, the photovoltaic material is arranged to receive all of the radiation from the exit aperture (sides of the slots) and this is assisted by transparent adhesive. Opposite sides 11A, 11B of the photovoltaic material receive radiation from the entry aperture, reflected off the opposite side surfaces 16, 17 of the optical component 15. In this case, the upper parts of the side surfaces 16, 17 may be Compound parabolic or hyperbolic curves as described with reference to FIG. 1 but the lower parts 16A, 17A may be inwardly directed and shaped so as to reflect radiation to the opposite sides of the photovoltaic material and these lower parts 16A, 17A nay be mirrored, (i.e. directly or indirectly include a mirrored surface).

In a similar way to the use of the photovoltaic cells of FIG. 1, a plurality of photovoltaic cells of FIG. 8 may be arranged in a similar manner to that shown in FIGS. 2 or FIG. 3 or FIG. 6 or FIG. 7. Thus they may be arranged side by side to form a panel and the optical axes of the optical components are parallel to each other but at an angle to the plane of the panel. In this case, we may provide a mirror surface 21 between each optical component to reflect solar radiation which would impinge on a side surface rather than the entry aperture to the entry aperture of an adjacent photovoltaic cell.

FIG. 10 is a section of a plurality of cells of the type shown in FIG. 8 at right angles to the section of FIG. 8 and is equivalent to the arrangement of FIG. 9 with respect to FIG. 1. This shows that the side surfaces 25, 26 in this section may also be of compound hyperbolic or parabolic shape.

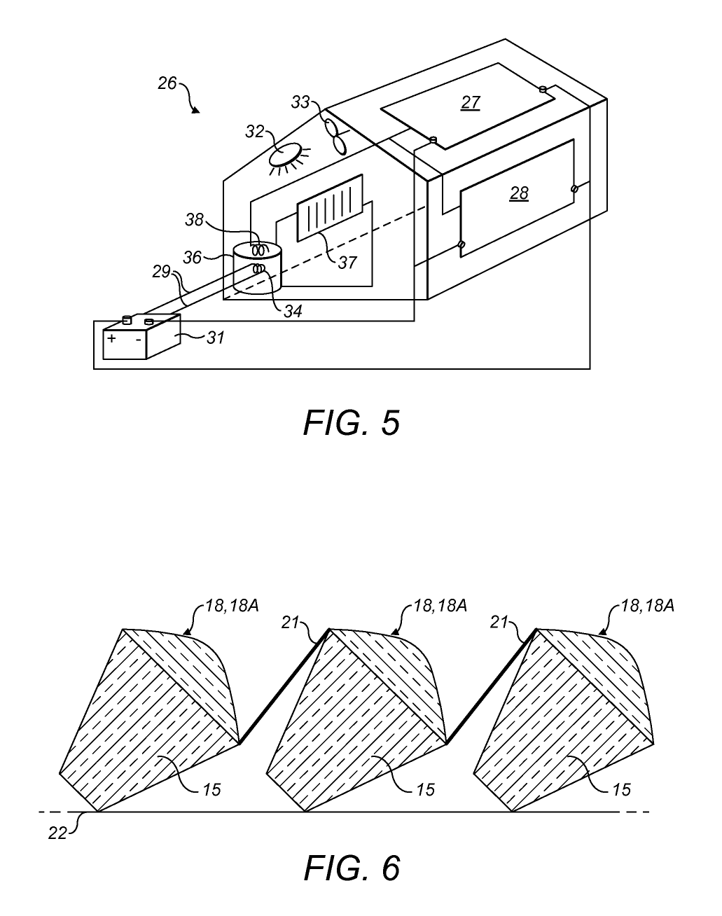

We now refer to FIG. 5 which shows how panels of photovoltaic components 10 may be applied to a building such as a greenhouse 26 (i.e. glass house) having glass walls, a conservatory or a glass roofed shopping centre. In the arrangement shown, the greenhouse 26 includes a first panel 27 of components 10 mounted on its roof, and a second similar panel 28. The panel 27 may be of the type shown in FIG. 2, and the second panel 28 of the target shown in FIG. 3.

Connected to each panel 27, 28, are electrical connections 29 which pass electricity produced by the photovoltaic material 12 in each panel to an electrical storage apparatus simply illustrated as a battery 31. Furthermore the electrical connections 29 may be connected to lamps 32 or air-conditioning apparatus such as fans 33 or to an electrical heating apparatus 34 for heating a supply of water in the form of a water tank 36.

The hot water tank 36 may be connected to space heating apparatus, for example in the form of radiators 37.

Furthermore, the cooling apparatus for cooling the photovoltaic material 12 may comprise an arrangement previously described utilising cooling water, and the cooling water may also be passed direct to a heat exchanger 38 within the hot water tank 36 to heat the water.

Such an arrangement is highly efficient. Thus sunlight passes in to the greenhouse in the usual way. Most of the sunlight will be intercepted and passed to the photovoltaic material 12 but in this case some passes through the first and second panels 27, 28 via the lower protective sheet 22 of FIG. 2. and so during the height of the day when the sun is at its most powerful, there is some shading within the greenhouse 26 to moderate the temperature appropriately.

Thus the arrangement of the invention in the form of the panels 27, 28 have two functions, firstly to moderate the sum of the sunlight passing to the wall and roof of the greenhouse 26, and secondly the intercepted sunlight is used to produce electricity via the photovoltaic material 12. Also, heat is removed from the photovoltaic material 12 and other parts of the photovoltaic components 10 by means of the water cooling system, and that heat is then passed to the water within the hot water tank 36.

At night, the temperature within the greenhouse 26 will normally fall considerably, and then the hot water within the tank 36 may be circulated through the radiator 37 to increase the temperature within the greenhouse which will improve and increase the growth of plants within the greenhouse. Furthermore, the electricity stored in the batteries 31 may be used to operate the lamps 32 which may be used to extend the effective daylight hours within the greenhouse, which once again will improve the growth of the plants within the greenhouse. Furthermore, during the middle of the day when the sunlight is particularly bright, the air-conditioning provided by the fans 33 may be switched on to once again moderate the temperature within the greenhouse. In some circumstances, the fans need not be switched on as a chimney/laminar flow effect can drive the ventilation without fans.

The horizontal and vertical configurations may be used in a new building (other than a greenhouse) and may be embedded in a double glazed roof and wall respectively. Thus the system including the double glazing would comprise the roof and walls of the building, that is, the envelope of the building, giving scope for dramatic and interesting looking buildings.

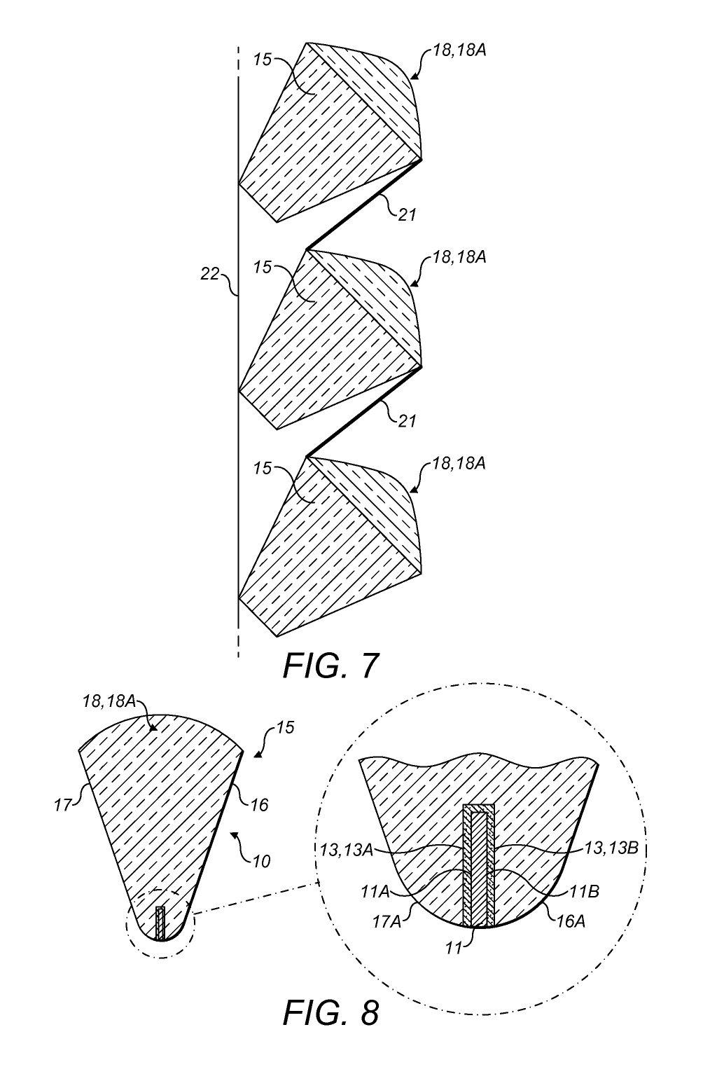

FIGS. 6 and 7 are views similar to views to FIGS. 2 and 3 except the panels illustrated are for use on the outer horizontal and vertical solid surfaces respectively of a building. In this case, there is no need for ambient light to pass through the panels and so the construction is slightly different.

If the panels 19 are spaced from the relevant wall surface, particularly in the case of the vertical configuration of FIG. 7, then air may be allowed to pass through the gap 40 between the outer surface of the vertical wall and the rear surface of the panel. In winter, ambient air may be passed to the lower edge of the gap between the wall and the panel and pass up and into the building at the upper end of the wall. In this way the heat from the rear of the photovoltaic cells will be passed into the building. In the summer, the arrangement may be different, Air from inside the building may be fed from a suitable aperture at the lower edge of the wall, and pass up through the gap 40 and outwardly to ambient outside the building, in this case drawing air from the inside of the building to thereby effectively air condition the building. Whist useful for solid walled buildings, this may also be used in greenhouses and transparent walls and roofs.

The mirror positions in FIGS. 6 and 7 permit more concentration than those in FIGS. 2 and 3 but reduce the ambient light reaching the interior. In some cases this is a useful benefit particularly in a vertical wall where ambient light may not be critical.

The use of panels as above described in a domestic house for instance (even in England) or similar building should generate more than enough electricity and heat to power the house electrically (and perhaps for a family car). In a more southerly climate such as Spain enough electricity should be produced to allow export of electricity to the grid is considerable. In a greenhouse in a good climate the system may becomes a power station whilst the running of the greenhouse is far more cost effective because of the reduction in cooling and heating loads.

Thus, in this way, we not only collect electricity using photovoltaic material as is well known, but also we utilise a smaller amount of photovoltaic material by providing an optical system which concentrates the solar radiation on to the material, and at the same time cool the material and other components and utilise that heat to keep the interior of the building warm when the outside temperature falls, for example at night. Whilst we have shown the apparatus of the invention applied to a greenhouse 26, it may similarly be utilised in, for example, glass conservatories attached to buildings, or simply applied to the relevant roof and walls of normal buildings, that is solid walls or could form translucent walls.

Thus we more fully utilise the solar photons falling on the apparatus, in order to transform them into useful output considering the application and to stop direct sunlight being transmitted where it would not be wanted.

FIG. 11 shows an arrangement of panels where the photovoltaic cell apparatuses are arranged in groups. Rather than have a mirror 21 adjacent the side surface of each individual optical component, there is provided a mirror surface 21 for a particular group of photovoltaic apparatus which is positioned so as to reflect radiation which does not reach the entry aperture of the cells of the first group, to the entry aperture of one or more of the cells of the second group.

The invention is not restricted to the details of the foregoing examples. Various other features may be incorporated in to the apparatus of the invention for even more effective use of the solar energy.

Thus, for example, the photovoltaic material 12 may be integrated with other electrical components. The photovoltaic material 12 may be divided in to separate cells, and cut-out diodes may be provided to cut-out those cells which are not fully within the sun. One of the problems is that if all of the cells are connected in series as is usual, then where part of the panel falls in to shade at particular times of the day, then the output of the panel may be reduced. By the use of cut-out diodes to cut out those cells which are not producing electricity, the output can be retained.

For example, other features can be incorporated on the device for more effective production of the output, for example, a light sensor, power conditioning, heat management, plug and play interconnects to adjoining components, etc.

For instance electronics for various purposes could be integrated into the apparatus so that the power received from the sun and converted by a photovoltaic cell would power the electronics such as sensors, controls and wireless communications with a central control unit of a building management system.

One of the differences between this and normal light powered systems with photovoltaic cells is that the optics is integrated into the same single component using the same heat sink for photovoltaic cell efficiency as for processor efficiency.

A second difference is that the optics is designed specifically to make maximum use of the solar photons reaching it as opposed to the normal glass cover for photovoltaic cells. This requires consideration of the varying position of the sun throughout the year, the varying solar spectrum depending on solar position and atmospheric conditions, the use of ambient and direct sunlight in different ways and the use of heat generated.

A third difference is that in order to achieve this efficient use of the solar photon the device must be correctly orientated, either permanently fixed in a particular position or temporarily positioned, whether altered automatically or manually.

In the case of the present optical element its robustness provides sufficient structure for the device to secure the electronic elements and even the heat management system and avoid the need of separate structured housing.

We envisage that in some circumstances the apparatus of the invention act as an intelligent envelope of the building, protecting the interior from the outside elements and transforming them to provide benign conditions and valuable resources inside.

We envisage various configurations by way of example only.

| Configuration | Application |
|---|---|
| Panel latitude angle Opaque Air cooled | Solar farm, roof mounted |
| retrofit | |
| Panel latitude angle Opaque Water cooled | Roof mounted retrofit |
| electricity and hot water | |
| Wall Translucent Water cooled | New buildings of all types |
| Wall Translucent Air cooled | New buildings of all types |
| Wall Opaque Water cooled | New and retrofit buildings |
| Wall Opaque Air cooled | New and retrofit buildings |
| Roof Translucent Water cooled | New buildings including |
| | greenhouses |
| Roof Translucent Air cooled | New buildings including |
| | greenhouses |
| Roof Opaque Water cooled | New buildings |
| Roof Opaque Air cooled | New buildings |

The invention is not restricted to the details of the foregoing examples.

Various preferred embodiments of the invention have been described and it is envisaged that these embodiments of the invention or parts thereof may be combined as appropriate for the use to which they may be put without departing from the scope of the invention.

References to dimensions including angles are by way of example only. Shapes and dimensions, particularly of reflective surfaces are by way of example and will differ depending on the situation in which the apparatus is to be used, for example where on Earth it is to be used and the (compass) direction in which the apparatus is mounted. Generally the dimensions and angles will be arranged with respect to the angle of the sun and for maximum effect for fixed installations will be aligned with respect to the direction of the sun at midday at the Equinox.

When applying the invention to a horticultural environment, particular plants in particular latitudes require certain amounts of light and certain frequencies such as ultra violet. The variables can be optimised to best achieve this. As a result it may not always be expedient to keep out all direct sunlight.

Secondly, in high latitude countries where air-conditioning is less likely to be required in the winter half of the year, it may be more efficient for overall energy generation for the building for the acceptance angle of the photovoltaic apparatus to only include the sun's summer path. In the winter the direct sunlight will bring needed light and warmth straight into the building, and a roof mounting with this configuration of the apparatus will be more valuable than the relatively small amount of electricity that will be generated if the acceptance angle included the sun's path for both summer and winter.

1-22. (canceled)

23. Apparatus comprising: an array of photovoltaic cells and, for each of the cells in the array, an optical component of transparent material of cross-section having a first surface forming an entry aperture for solar radiation, opposite side surfaces, photovoltaic material mounted opposite to the first surface for receiving solar radiation from the entry aperture, the opposite side surfaces being shaped to provide total internal reflection of solar radiation passing from the entry aperture to the photovoltaic material, the apparatus being configured and arranged to pass ambient light through the apparatus, whereby in use, solar radiation provides for electricity from the photovoltaic material as ambient light passes through the apparatus, and further including a mirror surface being positioned to reflect ambient light away from one of said side surfaces to an adjacent photovoltaic cell, with reflected ambient light passing through the cells to pass through the array.

24. Apparatus as claimed in claim 23, in which the opposite side surfaces are parabolic.

25. Apparatus as claimed in claim 23, in which the opposite side surfaces are hyperbolic.

26. Apparatus as claimed in claim 23, in which the photovoltaic material comprises mono-crystalline photovoltaic material.

27. Apparatus as claimed in claim 23, in which there are provided four side surfaces, each being curved so as to provide total internal reflection of solar radiation passing from the entry aperture to the photovoltaic material.

28. Apparatus as claimed in claim 1, wherein the photovoltaic material has a first face generally facing the first curved side surface to receive radiation from said first curved surface and a second opposite face generally facing the second curved side surface to receive radiation from said second curved surface.

29. Apparatus as claimed in claim 23, in which the mirror surface and adjacent photovoltaic apparatus are positioned so as to reflect radiation or light which would impinge on said side surface to the entry aperture of another photovoltaic apparatus.

30. Apparatus as claimed in claim 23, in which there are provided respective mirror surfaces for each photovoltaic cell and each of the mirror surfaces is positioned so as to reflect radiation or light which would impinge on one of the side surfaces of the optical component to the entry aperture of an adjacent one of the photovoltaic cells or an adjacent photovoltaic apparatus.

31. Apparatus as claimed in claim 23, in which the mirror surface is for a group of adjacent photovoltaic cells in the array and the mirror surface is positioned so as to reflect radiation or light which would impinge on the side surfaces of the respective optical components to the entry aperture of an adjacent one of the photovoltaic cells or an adjacent photovoltaic apparatus.

32. Apparatus as claimed in claim 23, further including:
a cooling element configured and arranged to cool the photovoltaic cells,
a heat transfer element configured and arranged to transfer the heat removed by the cooling element from the photovoltaic cells to a heat store, and
a heat removal element configured and arranged to extract the heat from the heat store.

33. Photovoltaic apparatus comprising:
one or more photovoltaic cells for receiving radiation,
a cooling element configured and arranged to cool the photovoltaic cells,
a heat transfer element configured and arranged to transfer the heat removed by the cooling element from the photovoltaic cells to a heat store, and
a heat removal element configured and arranged to extract the heat from the heat store.
